(19) United States
(12) Patent Application Publication
(10) Pub. No.: US 2025/0147436 A1
(43) Pub. Date: May 8, 2025

(54) METHODS OF METROLOGY

(71) Applicant: ASML NETHERLANDS B.V., Veldhoven (NL)

(72) Inventors: Chrysostomos BATISTAKIS, Eindhoven (NL); Huaichen ZHANG, Eindhoven (NL); Maxim PISARENCO, Son en Breugel (NL); Vahid BASTANI, Eindhoven (NL); Konstantin Sergeevich NECHAEV, Veldhoven (NL); Roy ANUNCIADO, Eindhoven (NL); Stefan Cornelis Theodorus VAN DER SANDEN, Nijmegen (NL)

(73) Assignee: ASML NETHERLANDS B.V., Veldhoven (NL)

(21) Appl. No.: 18/832,408

(22) PCT Filed: Jan. 23, 2023
(86) PCT No.: PCT/EP2023/051522

§ 371 Date: Jul. 23, 2024

(30) Foreign Application Priority Data
Feb. 21, 2022 (EP) 22157745.5
Apr. 8, 2022 (EP) 22167298.3
Sep. 5, 2022 (EP) 22193987.9

(51) Int. Cl. G03F 7/00

(52) U.S. Cl. CPC G03F 7/706841; G03F 7/70283; G03F 7/70625; G03F 7/706831

(57) ABSTRACT

A method for determining a parameter of interest relating to at least one structure formed on a substrate in a manufacturing process. The method includes: obtaining layout data relating to a layout of a pattern to be applied to the at least one structure, the pattern including the at least one structure; and obtaining a trained model, having been trained on metrology data and the layout data to infer a value and/or probability metric relating to a parameter of interest from at least the layout data, the metrology data relating to a plurality of measurements of the parameter of interest at a respective plurality of measurement locations on the substrate. A value and/or probability metric is determined relating to the parameter of interest at one or more locations on the substrate different from the measurement locations from at least layout data using the trained model.

### CROSS REFERENCE TO RELATED APPLICATIONS

This application claims priority of EP application Serial No. 22157745.5 which was filed on Feb. 21, 2022, EP application Serial No. 22167298.3 which was filed on Apr. 8, 2022, and EP application Serial No. 22193987.9 which was filed on Sep. 5, 2022 which are incorporated herein in its entirety by reference.

### BACKGROUND

### Field of the Invention

The present invention relates to methods of metrology performed to maintain performance in the manufacture of devices by patterning processes such as lithography. The invention further relates to methods of manufacturing devices using lithographic techniques. The invention yet further relates to computer program products for use in implementing such methods.

### Related Art

A lithographic process is one in which a lithographic apparatus applies a desired pattern onto a substrate, usually onto a target portion of the substrate, after which various processing chemical and/or physical processing steps work through the pattern to create functional features of a complex product. The accurate placement of patterns on the substrate is a chief challenge for reducing the size of circuit components and other products that may be produced by lithography. In particular, the challenge of measuring accurately the features on a substrate which have already been laid down is a critical step in being able to position successive layers of features in superposition accurately enough to produce working devices with a high yield.

A particularly important parameter of interest is overlay, which should, in general, be controlled to be within a few tens of nanometers in today's sub-micron semiconductor devices, down to a few nanometers in the most critical layers. Overlay quantifies the alignment of structures formed in respective layers; a lower overlay value indicates better alignment of the layers and as such overlay is an error metric which is typically to be minimized.

Another important parameter of interest or error metric, which is linked to overlay, is edge placement error (EPE). EPE is a measure of the difference between the intended and the printed features of an IC layout. The position error of the edge of a feature is determined by the features lateral position error (overlay, pattern shift) and the error in size of the feature (CD error). Part of the feature dimension and position errors is very local and stochastic in nature; e.g., dependent on local placement errors relating to local overlay (LOVL), local CD uniformity (LCDU), Line Edge Roughness (LER) and line width roughness (LWR). All of these may be important contributors to the EPE performance. As such, EPE is a composite metric comprising contributions associated with overlay and local placement errors from product structures across multiple layers. To measure the local placement errors, metrology may be performed directly on the product structure. This can be done using a scanning electron microscope (SEM) such as an e-beam metrology apparatus for example. To obtain a dense EPE fingerprint across wafer, a very large metrology effort is presently required, comprising measurement of many feature instances at many locations on the wafer.

Consequently, modern lithography apparatuses involve extensive measurement or ‘mapping’ operations prior to the step of actually exposing or otherwise patterning the substrate at a target location. However, there is typically only sparse overlay or EPE data available due to throughput requirements. Therefore, fitting models (polynomials) and/or other data indicative of overlay or EPE (such as alignment data) may be used to derive a dense overlay or EPE data map. Such a method is described, for example, in U.S. Pat. No. 10,990,018B2, which is incorporated herein by reference.

It would be desirable to improve inference and/or mapping of a parameter of interest such as overlay or EPE.

### SUMMARY OF THE INVENTION

According to a first aspect of the present invention there is provided a method for determining a parameter of interest relating to at least one structure formed on a substrate in a manufacturing process, the method comprising: obtaining layout data relating to a layout of a pattern to be applied to said structure, said pattern comprising said at least one structure; obtaining a trained model, having been trained on metrology data and said layout data to infer a value and/or probability metric relating to a parameter of interest from at least said layout data, the metrology data relating to a plurality of measurements of the parameter of interest at a respective plurality of measurement locations on the substrate; and determining a value and/or probability metric relating to the parameter of interest at one or more locations on the substrate different from said measurement locations from at least said layout data using said trained model.

According to a second aspect of the present invention there is provided a computer program product containing one or more sequences of machine-readable instructions for implementing calculating steps in a method according to the first aspect of the invention as set forth above

The invention yet further provides a processing arrangement and metrology device comprising the computer program of the second aspect.

These and other aspects and advantages of the apparatus and methods disclosed herein will be appreciated from a consideration of the following description and drawings of exemplary embodiments.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus suitable for use in an embodiment of the present invention;

FIG. 2 depicts a lithographic cell or cluster in which an inspection apparatus according to the present invention may be used;

FIG. 3 illustrates schematically measurement and exposure processes in the apparatus of FIG. 1, according to known practice;

FIG. 4(a) is a flowchart describing a method of training a model according to an overlay embodiment;

FIG. 4(b) is a flowchart describing a method of using the model trained according to FIG. 4(a) to regress a value for a parameter of interest according to an overlay embodiment;

FIG. 5(a) is a flowchart describing a method of training a model according to an edge placement error embodiment;

FIG. 5(b) is a flowchart describing a method of using the model trained according to FIG. 5(a) to regress a value for a parameter of interest according to an edge placement error embodiment;

FIG. 6 is a flowchart describing an overview of a training and inference flow according to a further embodiment;

FIG. 7 is a flowchart describing a method of using a model according to the embodiment depicted in FIG. 6;

FIG. 8(a) is a flowchart describing a method of training a first module of the model depicted in FIGS. 6 and 7; and

FIG. 8(b) is a flowchart describing a method of training a second module of the model depicted in FIGS. 6 and 7.

### DETAILED DESCRIPTION OF EXEMPLARY EMBODIMENTS

Before describing embodiments of the invention in detail, it is instructive to present an example environment in which embodiments of the present invention may be implemented.

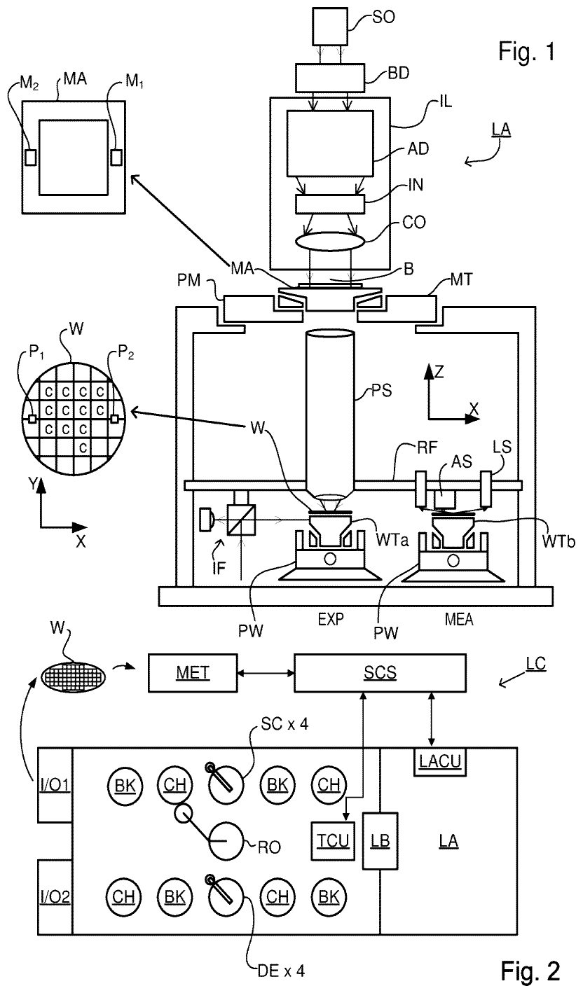

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation. For example, in an apparatus using extreme ultraviolet (EUV) radiation, reflective optical components will normally be used.

The patterning device support holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers, is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA-between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. On a single stage apparatus, the preparatory steps and exposure steps need to be performed sequentially on the single stage, for each substrate. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which lithocell LC is located also includes metrology system MET which receives some or all of the substrates W that have been processed in the lithocell. Metrology results are provided directly or indirectly to the supervisory control system SCS. If errors are detected, adjustments may be made to exposures of subsequent substrates.

Within metrology system MET, an inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it may be desirable that the inspection apparatus measure properties in the exposed resist layer immediately after the exposure. However, not all inspection apparatus have sufficient sensitivity to make useful measurements of the latent image. Therefore measurements may be taken after the post-exposure bake step (PEB) which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

The metrology step with metrology system MET can also be done after the resist pattern has been etched into a product layer. The latter possibility limits the possibilities for rework of faulty substrates but may provide additional information about the performance of the manufacturing process as a whole.

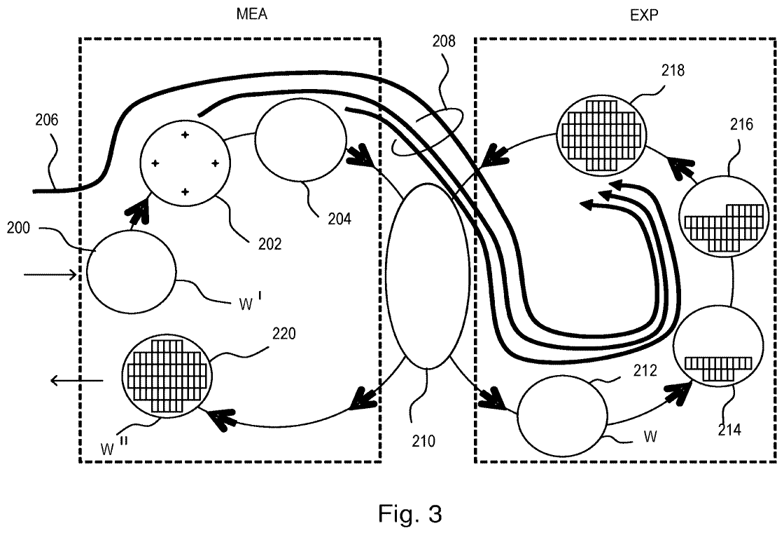

FIG. 3 illustrates the steps to expose target portions (e.g. dies) on a substrate W in the dual stage apparatus of FIG. 1. The process according to conventional practice will be described first. The present disclosure is by no means limited to dual stage apparatus of the illustrated type. The skilled person will recognize that similar operations are performed in other types of lithographic apparatus, for example those having a single substrate stage and a docking metrology stage.

On the left hand side within a dotted box are steps performed at measurement station MEA, while the right hand side shows steps performed at exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. Each patterning step can introduce positional deviations in the applied pattern, while subsequent processing steps progressively introduce distortions in the substrate and/or the pattern applied to it that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation. Some layers may be patterned by steps that are alternative or supplementary to exposure in the illustrated lithographic apparatus. Such alternative and supplementary techniques include for example imprint lithography, self-aligned multiple patterning and directed self-assembly. Similarly, other processing steps performed per layer (e.g., CMP and etch) may be performed on different apparatuses per layer.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a substrate model (sometimes referred to as the “wafer grid”), which maps very accurately the distribution of marks across the substrate, including any distortion relative to a nominal rectangular grid.

At step 204, a map of wafer height (Z) against X-Y position is measured also using the level sensor LS. Primarily, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. Where there is a choice of alignment marks on the substrate, and where there is a choice of settings of an alignment sensor, these choices are defined in an alignment recipe among the recipe data 206. The alignment recipe therefore defines how positions of alignment marks are to be measured, as well as which marks.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

Presently, overlay information is extracted using either direct metrology methods or indirect metrology methods. Direct metrology methods such as decap scanning electron microscope (SEM) metrology and/or high-voltage SEM (e.g., e-beam metrology) are too slow for inline overlay metrology and, in the case of decap metrology, destructive of the device being measured. Indirect metrology methods, such as scatterometry based metrology on optical targets, are typically performed on a small set of discrete locations, with a full field and/or full wafer overlay map being constructed by interpolating the measured overlay values at those discrete locations. However, the interpolation or polynomial fitting ignores any high-spatial frequency overlay component distribution which may originate from various process steps (e.g., etching and/or polishing steps). Therefore the subsequent overlay optimization based on this modeling is unaware of this high-spatial frequency overlay component distribution.

Edge placement error (EPE) is typically presently measured via the aforementioned direct methods, and therefore EPE metrology is typically slow (and sometimes destructive). As such, SEM metrology is only used on critical features and areas due to its limited throughput. The critical features and areas are normally determined using rule-based methods, without taking into account process proximity effects which are linked to the pattern density and perimeter density of the mask layout.

A method for predicting a parameter of interest such as overlay or EPE at high spatial frequency is proposed herein. Such a method may comprise obtaining metrology data comprising values for a parameter of interest (e.g., overlay or EPE) relating to a plurality of measurement locations on a substrate. In an overlay context, the metrology data may comprise, for example, after develop inspection (ADI) overlay data measured prior to certain processing steps such as etching and/or polishing (chemical-mechanical polishing CMP) or after etch inspection (AEI) overlay data measured subsequent to those processing steps. For example, the metrology data may comprise optically measured data, e.g., scatterometer data measured from a (e.g., sparse) layout of metrology targets. A metrology target in this context may comprise a structure exposed for the purpose of metrology, or another type of structure, such as actual (functional) device structure, on which metrology can be performed. In an EPE context, the metrology data may comprise sparse EPE measurements at a few measurement locations, e.g., as measured using an SEM/e-beam metrology tool.

The proposed method further comprises obtaining layout data, e.g., low resolution layout data such as layout data at a resolution defined by having a pixel size 0.1 μm or greater, 0.38 μm or greater, 0.4 μm or greater, 0.5 μm or greater, 0.8 μm or greater or approximately 1 μm. A trained model such as a machine learning model or a (convolutional) neural network may be used to regress said metrology data and low resolution layout data to a value for a parameter of interest at one or more locations on the substrate different from said measurement locations.

In an embodiment, the method may comprise determining a parameter of interest (e.g., overlay or EPE) spatial distribution or map over a substrate portion (e.g., an exposure field) and/or over the entire substrate.

A first embodiment will be described, for which the parameter of interest is overlay. The model may be trained using low resolution layout data, e.g., pattern density data with dense overlay metrology data. The dense overlay metrology data may comprise AEI overlay data. In embodiments where the model is trained to regress ADI overlay data to AEI overlay data, the trained model may further be trained using dense ADI overlay data. The model may be trained to regress the low resolution layout data and sparse overlay data to dense overlay data (e.g., dense AEI overlay data). In other words, the model may be trained to “densify” sparse metrology data using the low resolution layout data. In this manner, only a few measurements need to be made within a field during production, with the trained model used to interpolate the measurements to obtain a more dense map of the field.

The low resolution layout data may comprise a pattern density spatial distribution or pattern density map. Pattern density maps are low-resolution GDS (graphics design system) files or GDSII files. Due to the large size of GDS files, they are typically downscaled to a low resolution pattern density map in order to be able to process them sufficiently quickly for die-scale applications. A typical resolution of a pattern density map is a 1 μm pixel size.

Pattern density may be defined as the ratio of the patterned area to the total area of a window being considered. As such, the pattern density is dependent on the window chosen; i.e., it depends on the size and shape of the window. When using a large window, the pattern density at each location is averaged over a large area, which would exhibit a low-frequency profile. When using a small window, pattern density is more determined by the adjacent patterns in a very local area.

It is also known that certain processing effects affect (AEI) overlay, such as etch and CMP steps. For example, overlay may be affected by intra-die systematic (IDS) variation, which refers to the systematic variation that is repeated on every die, which originates from such fabrication steps repeated at the die level. It is known that IDS variation can be induced by the designed layout patterns on the mask. In particular, the local pattern density can have an effect. For example, etching is influenced by the pattern density PD. The chemistry of the etching plasma above the chip, and therefore the etch rate, selectivity and anisotropy depend on the fraction of photoresist and the fraction of etching waste products generated during the etch process. Another process that can be affected by pattern density is CMP.

As such, a suitable machine learning model can be trained to infer (e.g., AEI) overlay from low resolution layout data such as pattern density data in combination with sparse (e.g., ADI or AEI) overlay metrology. In this way, dense overlay maps (at field level or wafer level) which equate to AEI overlay may be obtained by sparse metrology. This allows such overlay mapping to be performed on a per-wafer basis, as it is possible to perform such sparse ADI metrology on every wafer. This in turn enables wafer-level overlay monitoring and control. The training may train the model to interpolate sparse AEI metrology to dense AEI overlay data using low resolution layout data, in which case only dense AEI overlay data is required as an input, in addition to the low resolution layout data. Alternatively, the training may train the model to interpolate sparse ADI metrology to dense AEI overlay data using low resolution layout data, in which case both dense ADI data and dense AEI overlay data may be used for training.

The model may be trained to operate at a field level, to interpolate sparse metrology data within a field to dense metrology data for that field (by its nature, the layout data will relate to a field). However, the model may be used to determine wafer overlay maps, e.g., by using a wafer scale fingerprint. One method would be to use the wafer scale fingerprint (e.g., as measured over one or more wafers) as in input to the model, such that the model is trained to apply the wafer scale fingerprint during interpolation, to provide a full wafer overlay map (dense overlay data over the whole wafer). In another approach, the model may be trained using dense overlay data over the whole wafer, on a per-field basis; e.g., per-field training based on wafer location. The model can then be used in combination with a wafer coordinate (i.e., identifying a field) to regress sparse overlay data to dense overlay data appropriate for that field or wafer region.

As an alternative to optical or scatterometer data, the metrology data used to train the model and as an input to the trained model to infer overlay, as described above, may comprise one of: dense connectivity e-test data (e.g., voltage contrast data) or dense direct SEM measurement data (e.g., CDSEM, de-cap SEM, cross-sectional SEM data). In this manner, the model may be trained to densify these types of data, based on a sparse metrology input.

In the context of this disclosure, sparse metrology data may comprise metrology data measured at 30-1000 points per wafer, e.g., fewer than 1000 points, fewer than 100 points, or fewer or equal to 30 points. This may translate, for example, to fewer than 20, fewer than 10, fewer than 5, fewer than 4, fewer than 3 or fewer than 2 measurements per field. By another metric, sparse sampling may describe a sampling with greater than 100 μm spacing in both x and y, greater than 1 mm spacing in both x and y, greater than 5 mm spacing in both x and y, greater than 10 mm spacing in both x and y, greater than 20 mm spacing in both x and y or greater than 30 mm spacing in both x and y. For training, dense sampling (dense metrology data) can describe more than 10 k points per wafer and/or a sampling at less than 100 μm spacing in both x and y.

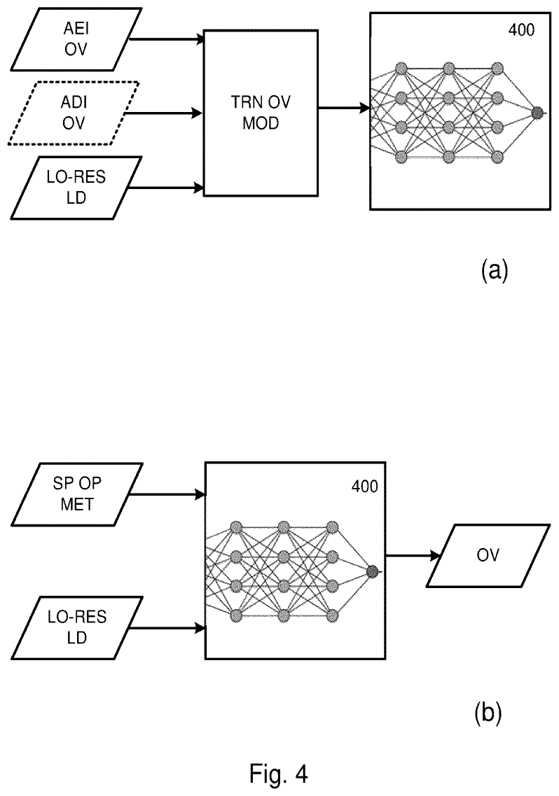

FIG. 4(a) is a flow diagram of a proposed training phase of such a method. Dense AEI overlay data AEI OV and low resolution layout data LO RES LD, e.g., pattern density data is used to train a machine learning model TRN OV MOD. Depending on its proposed application use-case (regression of AEI data or ADI data), dense ADI overlay data ADI OV may also be provided. The training may comprise training the model to interpolate or densify sparse sampling of the ADI metrology data or AEI metrology data using the low resolution layout data LO RES LD, such that the densified (modeled) data resembles the actual densely sampled metrology data (e.g., as close to within a threshold difference). The machine learning model may be a neural network or convolutional neural network (CNN). Once training is complete, the training phase will yield trained model 400, having been trained to infer overlay at any point of a particular layout or part thereof for which it is trained, based on sparse overlay metrology.

The pattern density data may comprise numerous (e.g., on the order of thousands) of cropped images of pattern density maps labeled by their relative measured overlay values. The measured overlay value may relate to overlay at a common point or inference point within all the images, e.g., overlay at the center of each image. The overlay may be measured via AEI metrology using a scatterometer or SEM for example.

The method may be repeated for various mask designs (i.e., pattern density maps), such that the machine learning model is trained to be able to directly regress sparse overlay data, a pattern density image and wafer coordinate to the expected overlay values.

The training step TRN OV MOD may comprise beginning training using pattern density maps or images covering a small area (small window), and performing an interpolation of overlay from (e.g., randomly sampled) locations within the small area based on the pattern density data therein, and comparing the interpolation result to the known densely measured AEI overlay data AEI OV (and/or ADI overlay data ADI OV). The can be repeated for stepwise or incrementally increasing areas of the pattern density map used to train the neural network until the modeling accuracy saturates; i.e., there is no longer any (significant) improvement in modeling accuracy. That will indicate that long-range pattern density effect is correctly taken into account.

FIG. 4(b) is a flow diagram illustrating an inference phase or production phase of the proposed method. Sparse overlay metrology data (e.g., ADI or AEI overlay metrology data) SP OV MET at a small number of locations (e.g., such that in-line per-wafer metrology is feasible) and low resolution layout data LO RES LD, e.g., pattern density data for the structures being exposed is fed into trained model 400 (e.g., trained according to the method just described). The trained model regresses this sparse overlay metrology data and low resolution layout data to overlay values OV over a field and/or the wafer. As such, the model can be used to generate dense field or wafer overlay maps based on inputting sparse overlay data and a pattern density map, where an overlay map may comprise a spatial distribution of overlay vectors across the field/substrate, each vector having a direction of the overlay and a magnitude of the overlay. Overlay can then be estimated for any wafer coordinate based on the overlay map.

A second embodiment, for which the parameter of interest is EPE, will now be described. As has already been discussed, it can be shown that surrounding pattern density can affect pattern behavior after exposure, due to developer loading effects, and particularly after etch, due to etch loading effects. Because of this, the same pattern can exhibit very different stochastic variability depending on its location within the die and the surrounding environment. Additionally, the local pattern density can be a good indicator of expected changes in stochastic pattern variability, particularly during after-etch inspection. Therefore, by not taking pattern density into account, valuable information which could improve accuracy of EPE metrology is being overlooked.

Process proximity effects, such as developer loading and/or etch loading, on EPE typically has a larger length scale compared to the optical proximity effect. Therefore using pattern density maps extracted (for example) at 1 μm grid, instead of using the full-resolution layout files (e.g., .GDS, .OAS) can provide a very significant benefit in terms of reducing computational load.

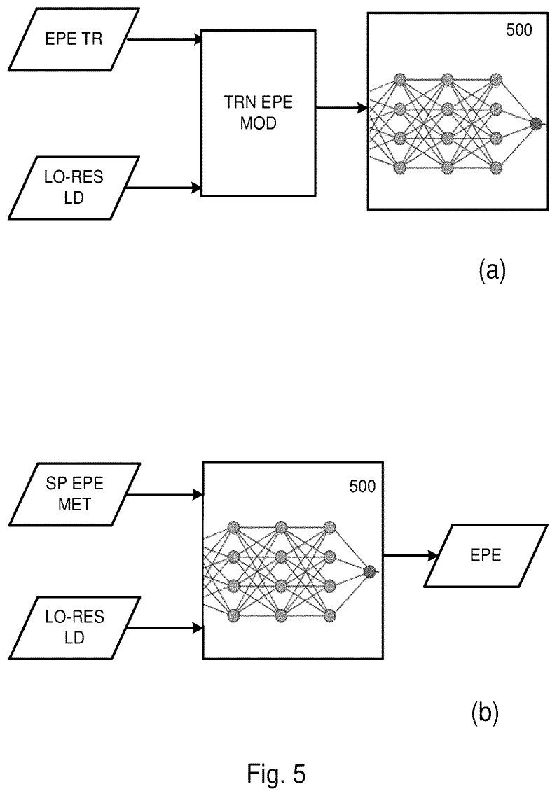

FIG. 5(a) depicts a flow diagram of a proposed training phase of such an EPE method. EPE training data EPE TR and low resolution layout data LO RES LD, e.g., pattern density data is used to train a machine learning model TRN EPE MOD. The EPE training data may be measured pre-etch or post-etch (e.g., EPE training data may comprise EPE ADI data or EPE AEI data). For example the EPE data may comprise densely sampled EPE data as measured using, for example, an SEM or other suitable metrology tool capable of EPE metrology.

As in the previous overlay embodiment, the low resolution layout data LO RES LD may comprise any of the layout data features described in the previous embodiment (e.g., in terms of resolution, for example). As such, the layout data may comprise pattern density data; e.g., numerous (e.g., on the order of thousands) of cropped images of pattern density maps. However, instead of overlay values, each image may be labeled by EPE values from the corresponding EPE training data.

The training may comprise training the model to interpolate or densify sparse sampling of the EPE training data using the low resolution layout data LO RES LD, such that the densified (modeled) data resembles the actual densely sampled EPE training data (e.g., as close to within a threshold difference). The machine learning model may be a neural network or convolutional neural network (CNN). As such, the training may comprise training the machine learning model such that it can directly use a pattern density image and a few sparse EPE measurements (e.g., randomly located within the image) in order to infer the effect of EPE at an inference point or point of interest (e.g., center of the image). Once training is complete, the training phase will yield trained model 500, having been trained to infer EPE at any point of a particular layout or part thereof for which it is trained, based on sparse EPE metrology.

As before, this training method may use pattern density images and associated EPE measurements from the EPE training data relating to features within the image as an input. For example, a sparse sampling of EPE measurements, e.g., which may be located/sampled randomly throughout the image, may be used to train the model so that it can infer the expected EPE at an inference point (e.g., the center of the image or any other point within the image which is not a sampled measurement point). The result of this inference can be compared to a known value (from the EPE training data) for the inference point. The area covered by the pattern density map can then be increased stepwise during training, with the increased area image and associated sparse EPE sampling used to feed the neural network until the prediction accuracy saturates. Saturation will indicate that long-range pattern density effects (e.g., both developer loading and etch loading effects) are fully taken into account. This method may be repeated for multiple fields across wafer, such that the network can learn the wafer scale fingerprints which occur e.g., after etch. The sparse sampling of the image may number fewer than 20, fewer than 10 or fewer than 6 points per image, for example.

The method may be repeated for various mask designs (i.e., pattern density maps), as before.

FIG. 5(b) is a flow diagram illustrating an inference phase or production phase of the proposed method according to this embodiment. Sparse EPE metrology data (e.g., ADI or AEI EPE metrology data) SP EPE MET at a small number of locations and low resolution layout data LO RES LD, e.g., pattern density data for the structures being exposed is fed into trained model 500 (e.g., trained according to the method just described). The trained model regresses this sparse EPE metrology data and low resolution layout data to EPE values EPE over a field and/or the wafer. As such, the model can be used to generate dense field or wafer EPE maps based on inputting sparse EPE data and a pattern density map, where an EPE map may comprise a spatial distribution of EPE vectors across the field/substrate, each vector having a direction of the EPE and a magnitude of the EPE. EPE can then be estimated for any wafer coordinate based on the EPE map.

While pattern density itself is not sufficient to fully define pattern stochastic variability, and hence EPE, the method of this embodiment will provide a very dense expected EPE map and can help to define the critical areas that need detailed inspection/metrology. At present, no method is able to provide a high-frequency map of EPE using sparse SEM measurements.

The predicted full wafer overlay map and/or EPE map may be used to optimize exposure setting for improving on-product overlay performance of the entire field or certain critical areas/features. Furthermore, the predicted (e.g., full-wafer) EPE and/or overlay map may be used to better define or identify critical areas, such that for example a more detailed inspection on these critical areas can be performed.

An additional embodiment will now be described, which may be used in the context of statistical analysis, e.g., for EPE reconstruction. For irregular or non-repetitive patterns, such as those of logic structures, there are many different features present. In such a case, lithography performance will vary from one feature to another because of variation in optical proximity. Full characterization of lithography performance would require SEM measurement of the full area containing all features, which is prohibitively expensive in terms of time. Therefore, this feature variation is presently handled by grouping features based on similarity in lithography/imaging behavior (e.g., as estimated via computational imaging simulation), thereby avoiding the need for extensive measurement of each individual feature. Each feature within a group is then assumed to behave similarly, such that only a subset of features per group needs measurement.

However, hot-spots or critical features, for which tolerances are low and therefore defect probability is relatively high, deviate from other features and tend to be grouped within small separate feature groups which are difficult to capture within a single SEM field-of-view. More specifically, these critical features are likely to have quite different lithography performance, which causes feature grouping to label them into their own small group. This increases the required metrology time. As such, grouping is particularly problematic with critical features. The number and density of critical features is expected to be low compared to the normal population. This makes it difficult to find a SEM field of view which contains a sufficient sample of groups which comprise critical features. Therefore, a larger SEM field of view is required, which contradicts the purpose of feature grouping, i.e., to reduce metrology effort.

Estimation of imaging and EPE performance per group is an inefficient use of data because it ignores the fact that photoresist chemo-physical behavior which is main driver for stochastics, and dose/focus which is a main driver for average behavior, are the same for all features. Therefore, correlation between lithography average and stochastic performance is expected regardless of feature layout.

It is therefore proposed to train a semi-supervised machine-learning model for prediction of a parameter of interest indicative of performance (e.g., a stochastic parameter such as probability-density-function (PDF) parameters of imaging metrics (e.g. mean & standard deviation of geometric parameters such as inter alia: CD, contour density) for all features of interest. The training may use sparse metrology data, e.g., SEM data for a subset of features, together with layout data such as a mask transmittance metric data such as local mask transmittance (LMT) data and/or imaging simulation data derived therefrom, such as aerial image data comprising simulated data of an aerial image generated via the mask (as described in the LMT/layout data) using a particular lithography tool (scanner) and particular scanner settings indicative of the actual tool and setting which are to be used. Additional predictors such as focus, dose, scanner known errors and logs, other scanner or process parameters, spatial coordinates or any other suitable parameter affecting imaging performance may also be used. The trained model may then be used to predict performance of all features based on layout data (e.g., LMT data and/or aerial image data).

The model may comprise a first module and a second module. The first module may perform a mapping of high dimensional layout data to a reduced space, capturing relevant imaging performance variation (e.g., in the form of a vector of relevant imaging properties). The relevance is determined mainly by the expert user. It depends on the input used as well as how the first module is designed. The second module may translate the vector of relevant imaging properties to an expected distribution metric of the parameter of interest.

As such, in the proposed model, the simulated imaging behavior of features may be used as continuous predictor for distribution parameters of a suitable performance metric such as an imaging and/or EPE metric. A (e.g., smooth) function may be trained using a measured subset of features (e.g., sparse metrology) to predict parameters for features which are not measured. In this way, information from all measured features contribute to estimation of the features not measured, rather than only those of the same group as is the case in a grouping methodology. This method helps in prediction of performance of different layout features, identifying hot-spots and/or ranking the layout features.

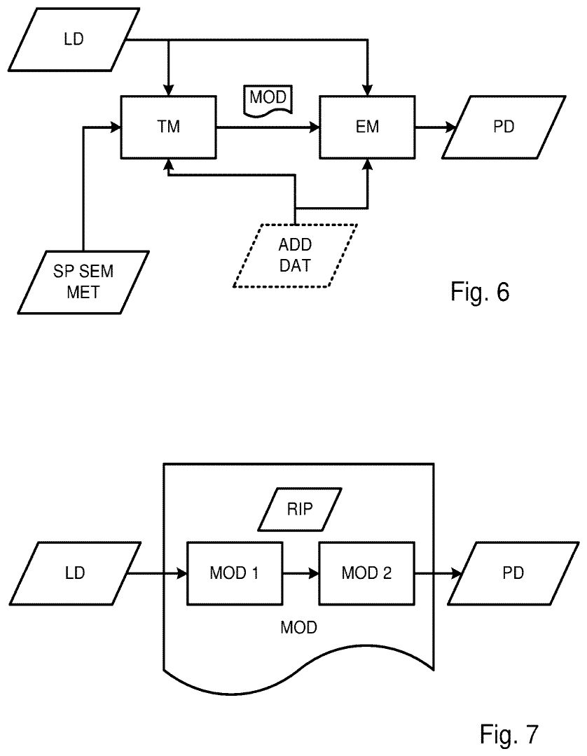

FIG. 6 is a flowchart providing an overview of such an embodiment: Sparse metrology data SP SEM MET relating to a set of (e.g., randomly selected) layout features is obtained. Such sparse metrology may relate to a portion or sub-module of the (e.g., logic) pattern or die being imaged. Such metrology data SP SEM MET may be obtained by SEM metrology, and the method may comprise the actual step of performing the metrology to obtain the metrology data SP SEM MET. A training step TM or fitting step may be performed to train or fit a predictive model MOD using the metrology data SP SEM MET and layout data LD (e.g., LMT data and/or data derived therefrom such as aerial image data) such that the trained model MOD is able (e.g. optimized) to predict probability data PD relating to one or more parameters of interest e.g., indicative of imaging performance based on the layout data LD. The layout data LD may for example comprise an LMT function per layout feature, for all features and may be obtained from a layout file (e.g., a .gds file).

The probability data PD may comprise a probability-density-function (PDF) for the parameter(s) of interest. The parameter of interest may be a statistical or stochastic metric (e.g., mean or standard deviation) of a geometric parameter such as one or more of CD, EPE and/or contour density for example. The probability data PD may relate to every layout feature (e.g., comprise a PDF for each feature). The model may be trained in a semi-supervised manner.

In addition to layout data LD, additional predictor data ADD DAT may be used in the training step TM. Additional predictor data may comprise, for example, lithography data or scanner data, such as dose and/or focus setting data.

The trained model MOD may then be used in an evaluation step EM, to determine probability data PD relating to imaging performance for some or all features in layout data LD (including features not measured and/or comprised within metrology data SP SEM MET), based on a layout data LD input. If trained using additional predictor data ADD DAT, then corresponding additional predictor data ADD DAT may be used in the evaluation step EM to determine probability data PD.

FIG. 7 is a flow diagram illustrating high-level architecture of the model MOD and evaluation step EM (FIG. 6). Model MOD may comprise a first module MOD 1 or layout feature optical relevance transformation module and a second module MOD2 or layout feature performance distribution predictor module. The first module MOD 1 translates the layout data LD (e.g., high dimensional LMT data) to a low-dimensional (e.g., vector) data space capturing relevant image properties RIP describing imaging performance variation between different features. The second module MOD 2 translates this relevant image properties RIP vector to the probability data PD as described above.

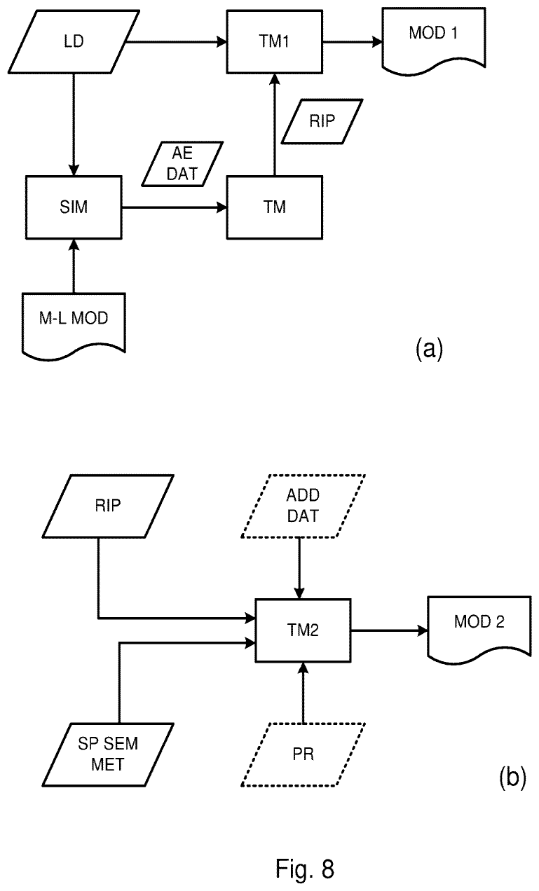

FIG. 8(a) is a flow diagram describing an example realization of a training procedure for first module MOD 1. This module may be trained in unsupervised manner using full layout data LD (e.g., LMTs of all features, regardless of whether they have been measured or not). Computational lithography or other optical simulation techniques may be performed SIM, e.g., using mask and lens model data M-L MOD. For example, this step may comprise generating simulated (e.g., 3D) aerial image data AE DAT. This is a desirable approach since it uses the lens and mask models M-L MOD to constrain the optical information which can be imaged on the wafer. For example, the 3D aerial image data AE DAT may comprise aerial images projected onto the wafer, including mask error, but excluding lithography system, photoresist and wafer effects. This high-dimensional aerial image data AE DAT may be reduced to low-dimensional relevant image properties RIP data by means of any suitable dimensionality reduction technique or mathematical decomposition technique (e.g. singular value decomposition SVD) and/or domain-specific imaging metrics (e.g. image log slope ILS). First Module MOD 1 is then trained TM1 as a lookup table or transformation function that is able to map and/or evaluate layout data to determine relevant image property data RIP.

FIG. 8(b) is a flow diagram describing an example overview of the second module MOD 2 training process. This module MOD 2 may be trained TM2 in a supervised manner using the (e.g., sparse) metrology data SP SEM MET. Additional data ADD DAT (e.g., one or more of scanner known errors and logs, process parameters such as focus and dose data, spatial coordinates) can be used in this step as additional predictors. The training objective for the training step TM2 may comprise, for example, a maximizing likelihood (ML) estimation or a-posterior probability (MAP) estimation of the observed measurement. In the example of MAP estimation, prior probabilities PR of the probability data parameters (e.g., PDF parameters) may be obtained from prior-knowledge, physical simulation, or typical features from same mask and used in the training.

In summary, the proposed method enables the use of a trained neural network and a few sparsely sampled overlay values to predict the high resolution full wafer overlay map, thereby providing a high accuracy densification of overlay data across wafer. In this way, per-wafer correction is possible.

In association with the hardware of the lithographic apparatus and the lithocell LC, an embodiment may include a computer program containing one or more sequences of machine-readable instructions for causing the processors of the lithographic manufacturing system to implement methods of model mapping and control as described above. This computer program may be executed for example in a separate computer system employed for the image calculation/control process. Alternatively, the calculation steps may be wholly or partly performed within a processor a metrology tool, and/or the control unit LACU and/or supervisory control system SCS of FIGS. 1 and 2. There may also be provided a data storage medium (e.g., semiconductor memory, magnetic or optical disk) having such a computer program stored therein in non-transient form.

Although specific reference may have been made above to the use of embodiments of the invention in the context of optical lithography, it will be appreciated that the invention may be used in other patterning applications, for example imprint lithography. In imprint lithography, topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Further embodiments of the invention are disclosed in the list of numbered clauses below:

1. A method for determining a parameter of interest relating to at least one structure formed on a substrate in a manufacturing process, the method comprising: obtaining layout data relating to a layout of a pattern to be applied to said structure, said pattern comprising said at least one structure; obtaining a trained model, having been trained on metrology data and said layout data to infer a value and/or probability metric relating to a parameter of interest from at least said layout data, the metrology data relating to a plurality of measurements of the parameter of interest at a respective plurality of measurement locations on the substrate; and determining a value and/or probability metric relating to the parameter of interest at one or more locations on the substrate different from said measurement locations from at least said layout data using said trained model.
2. A method according to clause 1, wherein said parameter of interest is overlay or edge placement error.
3. A method according to clause 1 or 2, wherein said trained model has been trained to interpolate said metrology data using said layout data to an expected value for the parameter of interest; and said determining a value and/or probability metric relating to the parameter of interest comprises determining the value for a parameter of interest at one or more locations on the substrate different from said measurement locations from said metrology data and said layout data using said trained model
4. A method according to clause 1, 2 or 3, wherein said metrology data comprises after develop inspection metrology data measured prior to an etching and/or a polishing step.
5. A method according to clause 1, 2 or 3, wherein said metrology data comprises after etch inspection metrology data measured subsequent to an etching and/or a polishing step.
6. A method according to any preceding clause, wherein said metrology data is measured using a scatterometer.
7. A method according to any preceding clause, wherein said metrology data comprises one of: connectivity e-test data or scanning electron microscope measurement data.
8. A method according to any preceding clause, wherein said plurality of measurement locations number fewer than 1000 locations per substrate.
9. A method according to any of clauses 1 to 7, wherein said plurality of measurement locations number fewer than 100 locations per substrate.
10. A method according to any of clauses 1 to 7, wherein said plurality of measurement locations number fewer than 30 locations per substrate.
11. A method according to any preceding clause, wherein said plurality of measurement locations have an average spacing greater than 1 mm spacing in both directions of a substrate plane.
12. A method according to any of clauses 1 to 10, wherein said plurality of measurement locations have an average spacing greater than 10 mm in both directions of a substrate plane.
13. A method according to any of clauses 1 to 10, wherein said plurality of measurement locations have an average spacing greater than 30 mm in both directions of a substrate plane.
14. A method according to any preceding clause, wherein said layout data comprises low resolution layout data, at a resolution defined by having a pixel size 0.5 μm or greater.
15. A method according to any preceding clause, wherein said layout data comprises a pattern density spatial distribution.
16. A method according to any preceding clause, wherein said determining step comprises determining a spatial distribution of said parameter of interest over at least an exposure field.
17. A method according to any preceding clause, wherein said determining step uses substrate position data to determine a spatial distribution of said parameter of interest over the substrate, the trained model having been trained per-field based on the substrate location data.
18. A method according to clause 16 or 17, comprising using said spatial distribution of said parameter of interest to optimize one or more exposure settings in the manufacturing process and/or identify one or more areas or structures for further inspection.
19. A method according to any preceding clause, comprising performing said method for every substrate of a substrate lot in the manufacturing process.
20. A method according to any preceding clause, comprising an initial step of:
obtaining training layout data comprising a similar type of data to said layout data;
obtaining training metrology data corresponding to the training layout data; and
training a machine learning model with said training metrology data and dense layout data to obtain said trained model.
   21. A method according to clause 20, wherein said training metrology data comprises at least after-etch inspection metrology data measured subsequent to an etching and/or polishing step.
   22. A method according to clause 21, wherein said training metrology data further comprises after-develop inspection metrology data measured prior to an etching and/or polishing step, the training step comprising training the machine learning model to interpolate a sparse sampling of after-develop inspection metrology data to a denser sampling of after-etch inspection metrology data.
   23. A method according to any of clauses 20 to 22, wherein said training metrology data comprises densely sampled metrology data, sampled at more than 10000 points per substrate and/or at less than 100 μm spacing in both directions of a substrate plane.
   24. A method according to any of clauses 20 to 23, wherein said training step comprises training the machine learning model to interpolate a sparse sampling of said metrology data to a denser sampling of said metrology data using said layout data.
   25. A method according to any of clauses 20 to 24, wherein said training step comprises using layout data relating to a small substrate area at the beginning of said training and increasing the substrate area covered by the layout data during said training until modeling accuracy of said model saturates.
   26. A method according to any of clauses 20 to 25, wherein said layout data and training layout data comprise pattern density images.
   27. A method according to clause 26, wherein said training metrology data comprises parameter of interest values describing the parameter of interest at a common inference point within all the training layout data images.
   28. A method according to any of clauses 20 to 27, comprising obtaining a substrate scale fingerprint relating to the training metrology data; and training the model to apply the substrate scale fingerprint during interpolation to provide a full substrate parameter of interest distribution.
   29. A method according to any of clauses 20 to 27, comprising training the model on a per-field basis based on field location on a substrate.
   30. A method according to clause 1, wherein the trained model comprises a first module being operable to translate said layout data to a reduced space which captures relevant imaging performance variation and a second module operable to translate said relevant imaging performance variation to the probability metric relating to the parameter of interest.
   31. A method according to clause 30, comprising training said first module unsupervised using said layout data and relevant imaging performance data derived from said layout data.
   32. A method according to clause 30 or 31, wherein said layout data comprises mask transmittance metric data and/or imaging simulation data derived therefrom.
   33. A method according to clause 32, wherein said imaging simulation data comprises aerial image data.
   34. A method according to clause 32 or 33, comprising a simulation step to determine said imaging simulation data from said layout data.
   35. A method according to any of clauses 30 to 34, comprising training said second module using said layout data and said metrology data.
   36. A method according to clause 35, wherein a training objective for training said second module comprises a maximizing likelihood estimation or a-posterior probability estimation of the metrology data.
   37. A method according to clause 35 or 36, wherein said training of said second module is at least semi-supervised based on said metrology data.
   38. A method according to clause 35, 36 or 37, wherein said training of said second module comprises using additional data relating to one or more scanner and/or imaging process parameters forming said structure on the substrate; and said determining a value and/or probability metric relating to the parameter of interest at one or more locations on the substrate also uses corresponding additional data.
   39. A method according to any of clauses 30 to 38, wherein the probability metric comprise an expected probability distribution metric of the parameter of interest.
   40. A method according to any of clauses 30 to 39, wherein said metrology data relates to a subset of features within a pattern.
   41. A method according to clause 40, wherein said determining a value and/or probability metric relating to the parameter of interest at one or more locations on the substrate comprises determining a probability metric relating to the parameter of interest for every feature within said pattern.
   42. A method according to any of clauses 30 to 41, wherein the parameter of interest comprises a statistical parameter relating to geometric metric.
   43. A method according to clause 42, wherein the geometric metric comprises edge placement error, critical dimension or a contour metric.
   44. A method according to any of clauses 30 to 43, wherein said metrology data comprises scanning electron microscope data.
   45. A computer program comprising program instructions operable to perform the method of any preceding clause, when run on a suitable apparatus.
   46. A non-transient computer program carrier comprising the computer program of clause 45.
   47. A processing arrangement comprising:
a computer program carrier comprising the computer program of clause 45; and
a processor operable to run said computer program.
   48. A metrology device comprising the processing arrangement of clause 47.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A method for determining a parameter of interest relating to at least one structure formed on a substrate in a manufacturing process, the method comprising:
obtaining layout data relating to a layout of a pattern to be applied to the at least one structure, the pattern comprising the at least one structure;
obtaining a trained computer model, having been trained on metrology data and the layout data to infer a value and/or probability metric relating to the parameter of interest from at least the layout data, the metrology data relating to a plurality of measurements of the parameter of interest at a respective plurality of measurement locations on the substrate; and
determining, by a hardware computer system, a value and/or probability metric relating to the parameter of interest at one or more locations on the substrate different from the measurement locations from at least the layout data using the trained model.

2. The method as claimed in claim 1, wherein the parameter of interest is overlay or edge placement error.

3. The method as claimed in claim 1, wherein the trained model has been trained to interpolate the metrology data using the layout data to an expected value for the parameter of interest; and the determining a value and/or probability metric relating to the parameter of interest comprises determining the value for a parameter of interest at one or more locations on the substrate different from the measurement locations from the metrology data and the layout data using the trained model.

4. The method as claimed in claim 1, wherein the metrology data comprises after develop inspection metrology data measured by a scatterometer.

5. The method as claimed in claim 1, wherein the metrology data comprises after etch inspection metrology data measured subsequent to an etching and/or a polishing step.

6. The method as claimed in any of claim 1, wherein the metrology data comprises connectivity e-test data or scanning electron microscope measurement data.

7. The method as claimed in claim 1, wherein the layout data comprises a pattern density spatial distribution.

8. The method as claimed in claim 1, wherein the determining comprises determining a spatial distribution of the parameter of interest over at least an exposure field.

9. The method as claimed in claim 1, wherein the determining uses substrate position data to determine a spatial distribution of the parameter of interest over the substrate, the trained model having been trained per-field based on the substrate location data.

10. The method as claimed in claim 8, further comprising using the spatial distribution of the parameter of interest to optimize one or more settings in the manufacturing process and/or identify one or more areas or structures for further inspection.

11. The method as claimed in claim 1, further comprising:
obtaining training layout data comprising a similar type of data as the layout data;
obtaining training metrology data corresponding to the training layout data; and
training a machine learning model with the training metrology data and dense layout data to obtain the trained model.

12. The method as claimed in claim 11, wherein the training metrology data comprises at least after-etch inspection metrology data measured subsequent to an etching and/or polishing step.

13. The method as claimed in claim 12, wherein the training metrology data further comprises after-develop inspection metrology data, and the training comprises training the machine learning model to interpolate a sparse sampling of after-develop inspection metrology data to a denser sampling of after-etch inspection metrology data.

14. The method as claimed in claim 11, wherein the layout data and training layout data comprise pattern density images.

15. (canceled)

16. A non-transitory computer-readable medium having instructions therein, the instructions, when executed by a computer system, configured to cause the computer system to at least:
obtaining layout data relating to a layout of a pattern to be applied to at least one structure formed on a substrate in a manufacturing process, the pattern comprising the at least one structure;
obtaining a trained computer model, having been trained on metrology data and the layout data to infer a value and/or probability metric relating to a parameter of interest from at least the layout data, the metrology data relating to a plurality of measurements of the parameter of interest at a respective plurality of measurement locations on the substrate; and
determining, by a hardware computer system, a value and/or probability metric relating to the parameter of interest at one or more locations on the substrate different from the measurement locations from at least the layout data using the trained model.

17. The medium as claimed in claim 16, wherein the parameter of interest is overlay or edge placement error.

18. The medium as claimed in claim 16, wherein the trained model has been trained to interpolate the metrology data using the layout data to an expected value for the parameter of interest; and the instructions configured to cause the computer system to determine a value and/or probability metric relating to the parameter of interest are configured to cause the computer system to determine the value for a parameter of interest at one or more locations on the substrate different from the measurement locations from the metrology data and the layout data using the trained model.

19. The medium as claimed in claim 16, wherein the instructions configured to cause the computer system to determine a value and/or probability metric relating to the parameter of interest are configured to cause the computer system to determine a spatial distribution of the parameter of interest over at least an exposure field.

20. The medium as claimed in claim 16, wherein the instructions configured to cause the computer system to determine a value and/or probability metric relating to the parameter of interest are configured to cause the computer system to use substrate position data to determine a spatial distribution of the parameter of interest over the substrate, the trained model having been trained per-field based on the substrate location data.

21. The medium as claimed in claim 16, wherein the instructions are further configured to cause the computer system to use the spatial distribution of the parameter of interest to optimize one or more settings in the manufacturing process and/or identify one or more areas or structures for further inspection.
